(19) United States
(12) Patent Application Publication
(10) Pub. No.: US 2007/0236896 A1
(43) Pub. Date: Oct. 11, 2007

(54) Wiring board in which silver is deposited near via-conductor and method for manufacturing wiring board

(75) Inventors: Masayoshi Takeuchi, Fukushima-ken (JP); Shinji Murata, Fukushima-ken (JP)

Correspondence Address: BEYER WEAVER LLP, P.O. BOX 70250, OAKLAND, CA, 94612-0250, US

(73) Assignee: ALPS ELECTRIC CO., LTD.

(21) Appl. No.: 11/714,514

(22) Filed: Mar. 5, 2007

(30) Foreign Application Priority Data
Mar. 23, 2006 (JP) 2006-080727

(51) Int. Cl. H05K 7/00; H05K 1/18

(52) U.S. Cl. 361/748; 29/829

(57) ABSTRACT

A wiring board in which silver is deposited near a via-conductor includes a ceramic substrate having a via-hole, a via-conductor disposed in the via-hole, and a metal thin-film pattern which is disposed on the ceramic substrate such that the metal thin-film pattern is connected to the via-conductor. The via-conductor contains silver or a material principally containing silver. A silver deposit that is a piece of the via-conductor is disposed on a surface portion of the ceramic substrate that is located near the via-hole. A catalyst layer containing a metal material is disposed over an exposed face of the via-conductor and the surface portion of the ceramic substrate. A metal layer is disposed on the catalyst layer. The metal thin-film pattern is disposed over the metal layer and the ceramic substrate.

### BACKGROUND OF THE INVENTION

1. Field of the Invention

The present invention relates to a wiring board suitable for various electric apparatuses and electronic circuit units and also relates to a method for manufacturing such a wiring board.

2. Description of the Related Art

A conventional wiring board and a method for manufacturing the wiring board will now be described with reference to the accompanying drawings. FIG. 7 shows a principal part of the conventional wiring board in cross section. FIG. 8 illustrates a first step of the method, FIG. 9 illustrates a second step of the method, FIG. 10 illustrates a third step of the method, and FIG. 11 illustrates a fourth step of the method.

The conventional wiring board has a configuration as described below. With reference to FIG. 7, the conventional wiring board includes a ceramic substrate 51 having a via-hole 51a. The via-hole 51a accommodates a via-conductor 52.

Since cavities 53 are formed in the ceramic substrate 51 and the via-conductor 52 and also formed between the via-conductor 52 and the wall of the via-hole 51a when the ceramic substrate 51 and the via-conductor 52 are fired, a boehmite layer 54 and a polyimide layer 55 are provided on the ceramic substrate 51 in that order such that the cavities 53 are occupied by portions of the boehmite and polyimide layers 54 and 55.

The boehmite and polyimide layers 54 and 55 are partly removed by grinding such that portions of the boehmite and polyimide layers 54 and 55 remain in the cavities 53. Therefore, the ceramic substrate 51 has a flat face. The conventional wiring board further includes a metal thin-film pattern 56 disposed on the flat face thereof.

The conventional wiring board is manufactured as described below. In the first step shown in FIG. 8, the ceramic substrate 51 including the via-conductor 52 is fired, whereby the cavities 53 are formed in the ceramic substrate 51 and the via-conductor 52 and also formed between the via-conductor 52 and the wall of the via-hole 51a.

In the second step shown in FIG. 9, the boehmite layer 54 and the polyimide layer 55 are provided over an exposed face of the via-conductor 52 and the ceramic substrate 51 in that order such that the cavities 53 are occupied by the portions of the boehmite and polyimide layers 54 and 55.

In the third step shown in FIG. 10, the polyimide layer 55 is partly removed by grinding. In the fourth step shown in FIG. 11, the boehmite layer 54 is then partly removed by grinding. This allows the ceramic substrate 51 to have such a flat face with the cavities 53 occupied by the portions of the boehmite and polyimide layers 54 and 55.

As shown in FIG. 7, the metal thin-film pattern 56 is formed on the flat face of the ceramic substrate 51, whereby the conventional wiring board is obtained.

Since the boehmite layer 54 and the polyimide layer 55 need to be partly removed by grinding such that the ceramic substrate 51 and the via-conductor 52 are planarized, there is a problem in that the manufacturing cost of the conventional wiring board is high and the efficiency of the method is low.

### SUMMARY OF THE INVENTION

The present invention has been made to solve the above problem. It is an object of the present invention to provide a wiring board that can be manufactured at low cost. It is another object of the present invention to provide a method for manufacturing such a wiring board with high efficiency.

In order to achieve the above object, the present invention provides a wiring board in which silver is deposited near a via-conductor. The wiring board includes a ceramic substrate having a via-hole, a via-conductor disposed in the via-hole, and a metal thin-film pattern which is disposed on the ceramic substrate such that the metal thin-film pattern is connected to the via-conductor. The via-conductor contains silver or a material principally containing silver. A silver deposit that is a piece of the via-conductor is disposed on a surface portion of the ceramic substrate that is located near the via-hole. A catalyst layer containing a metal material is disposed over an exposed face of the via-conductor and the surface portion of the ceramic substrate. A metal layer is disposed on the catalyst layer. The metal thin-film pattern is disposed over the metal layer and the ceramic substrate.

In the wiring board, the catalyst layer and the metal layer have portions occupying cavities present between the ceramic substrate and the via-conductor and need not be removed. Hence, a grinding step, which is necessary to manufacture a conventional wiring board, is not necessary to manufacture the wiring board. The wiring board can therefore be manufactured at low cost with high efficiency.

Since the silver deposit is disposed on the surface portion of the ceramic substrate, the catalyst layer overlying the silver deposit is tightly bonded to the silver deposit and is hardly released therefrom. Since the catalyst layer and the metal layer extend over the exposed face of the via-conductor to the ceramic substrate and have gentle slopes, the via-conductor can be protected from being damaged and the metal thin-film pattern can be prevented from being released from the ceramic substrate.

In the wiring board, the catalyst layer preferably contains palladium.

The presence of palladium allows the catalyst layer to be tightly bonded to the via-conductor and the metal layer.

In the wiring board, the metal layer preferably contains nickel phosphide.

The presence of nickel phosphide in the metal layer prevents the migration of the via-conductor and the metal thin-film pattern.

In the wiring board, the ceramic substrate is preferably made of low-temperature co-fired ceramic and the metal thin-film pattern preferably contains copper or a material principally containing copper.

When the ceramic substrate is made of low-temperature co-fired ceramic, the silver deposit can be readily formed at relatively low temperature and the metal thin-film pattern can be readily formed using copper so as to have high conductivity.

The present invention further provides a method for manufacturing a wiring board in which silver is deposited near a via-conductor. The method includes a step of forming a via-hole in a ceramic green sheet; a step of providing a conductive paste containing silver or a metal material principally containing silver in the via-hole; a step of firing the green sheet and the conductive paste such that the green sheet is converted into the ceramic substrate, the conductive paste is converted into the via-conductor, silver in the conductive paste is diffused in the ceramic substrate, and a silver deposit is formed on a surface portion of the ceramic substrate that is located near the via-hole; a step of providing a catalyst layer containing a metal material over an exposed face of the via-conductor and the surface portion of the ceramic substrate; and a step of providing a metal layer on the catalyst layer.

According to the method, the catalyst layer and the metal layer have portions occupying cavities present between the ceramic substrate and the via-conductor and need not be removed. Hence, the method need not include a grinding step necessary to manufacture a conventional wiring board and the wiring board can be manufactured at low cost with high efficiency. Since the silver deposit is disposed on the surface portion of the ceramic substrate, the catalyst layer overlying the silver deposit is tightly bonded to the silver deposit and is hardly released therefrom.

In the method, the metal layer is preferably overlaid with a metal thin-film pattern containing copper or a material principally containing copper.

The metal thin-film pattern can be readily formed using copper so as to have high conductivity.

In the method, the catalyst layer preferably contains palladium.

The presence of palladium allows the catalyst layer to be tightly bonded to the via-conductor and the metal layer.

In the method, the metal layer preferably contains nickel phosphide.

The presence of nickel phosphide in the metal layer prevents the migration of the via-conductor and the metal thin-film pattern.

In the method, the green sheet preferably contains a material for forming a low-temperature co-fired ceramic substrate and the green sheet and the conductive paste are preferably fired at a temperature of about 800° C. to 900° C.

This allows the silver deposit to have good properties.

### BRIEF DESCRIPTION OF THE DRAWINGS

FIG. 1 is a sectional view of a principal part of a wiring board according to the present invention;

FIG. 2 is an illustration showing a first step of a method for manufacturing a wiring board according to the present invention;

FIG. 3 is an illustration showing a second step of the method;

FIG. 4 is an illustration showing a third step of the method;

FIG. 5 is an illustration showing a fourth step of the method;

FIG. 6 is an illustration showing a fifth step of the method;

FIG. 7 is a sectional view of a principal part of a conventional wiring board;

FIG. 8 is an illustration showing a first step of a conventional method for manufacturing the conventional wiring board;

FIG. 9 is an illustration showing a second step of the conventional method;

FIG. 10 is an illustration showing a third step of the conventional method; and

FIG. 11 is an illustration showing a fourth step of the conventional method.

### DESCRIPTION OF THE PREFERRED EMBODIMENTS

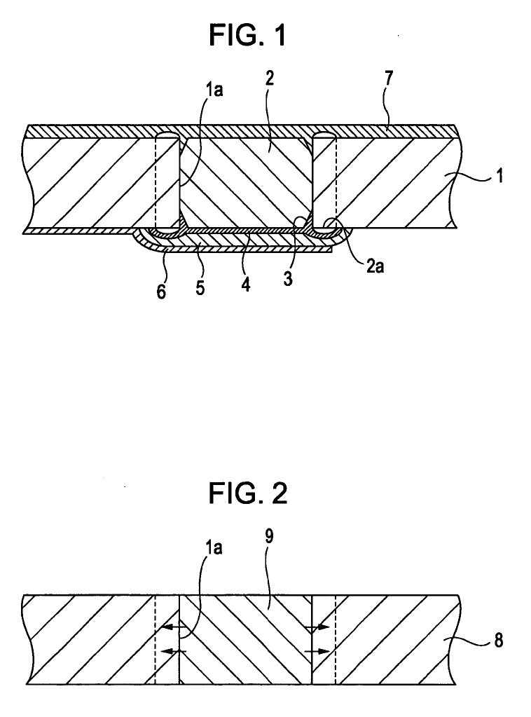

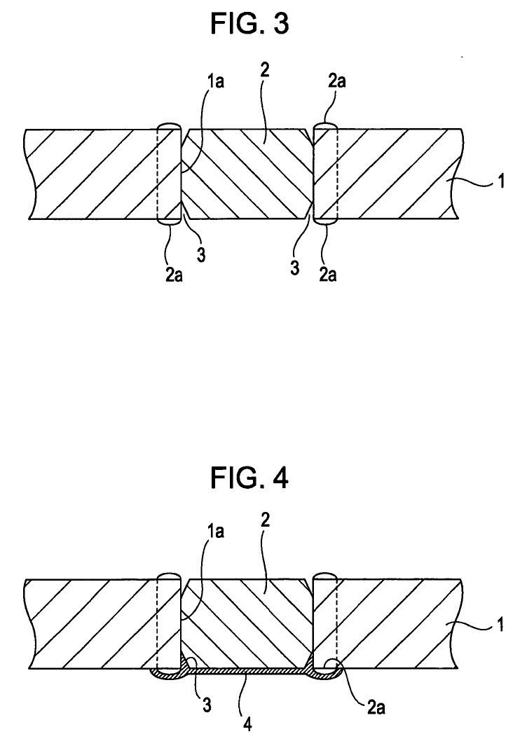

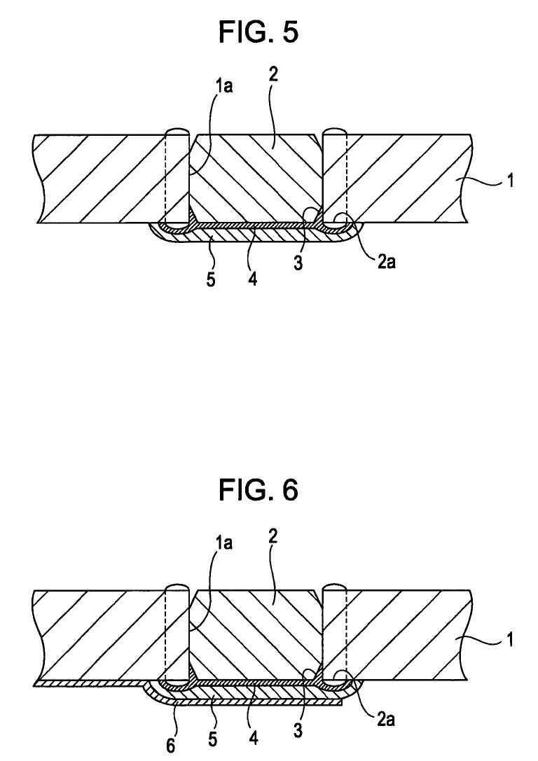

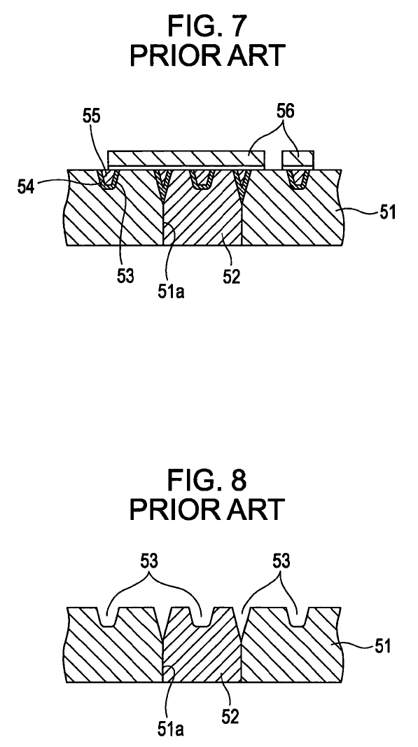

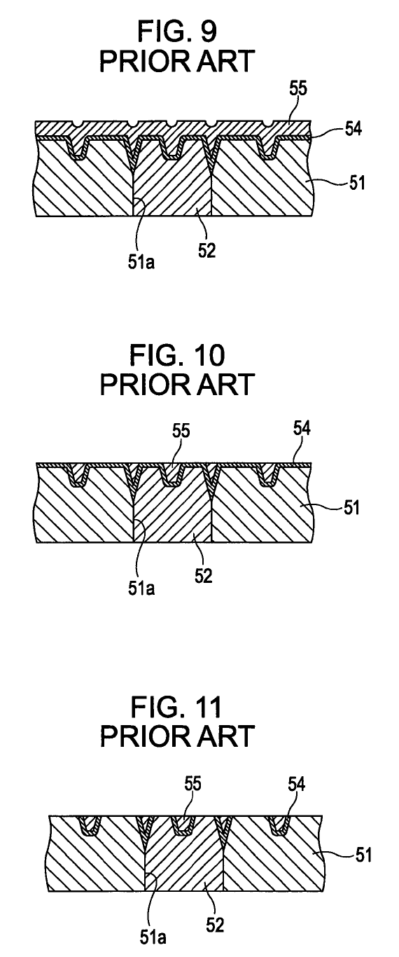

Embodiments of the present invention will now be described with reference to the accompanying drawings. FIG. 1 shows a principal part of a wiring board according to the present invention in cross section. FIG. 2 illustrates a first step of a method for manufacturing the wiring board according to the present invention. FIG. 3 illustrates a second step of the method. FIG. 4 illustrates a third step of the method. FIG. 5 illustrates a fourth step of the method. FIG. 6 illustrates a fifth step of the method.

The wiring board has a configuration as described below. With reference to FIG. 1, the wiring board includes a ceramic substrate 1 having a via-hole 1a, a via-conductor 2 disposed in the via-hole 1a, and a metal thin-film pattern 6. The ceramic substrate 1 is made of low-temperature co-fired ceramic (LTCC). The via-conductor 2 contains sliver or a material principally containing silver. A silver deposit 2a that is a piece of the via-conductor 2 is disposed on a surface portion of the ceramic substrate 1 that is located near the via-hole 1a.

Cavities 3 are present between the via-conductor 2 and the wall of the via-hole 1a, the cavities 3 being formed together with the silver deposit 2a when the ceramic substrate 1 and the via-conductor 2 are fired. A catalyst layer 4 that contains palladium or a metal material principally containing palladium extends over an exposed face of the via-conductor 2, the surface portion of the ceramic substrate 1, and the silver deposit 2a. The catalyst layer 4 has portions that occupy the cavities 3.

A metal layer 5 containing nickel phosphide overlies the catalyst layer 4. The metal thin-film pattern 6 contains copper or a metal material principally containing copper and extends over the metal layer 5 to the ceramic substrate 1.

A thick conductive pattern 7 is disposed on a face of the ceramic substrate 1 that is opposed to the metal thin-film pattern 6. The conductive pattern 7 is connected to the via-conductor 2. The configuration of the wiring board is as described above.

In this embodiment, the conductive pattern 7 has a large thickness. A thin metal pattern may be used instead of the conductive pattern 7.

The method will now be described with reference to FIGS. 2 to 6. In the first step shown in FIG. 2, the via-hole 1a is formed in a green sheet 8 for forming the ceramic substrate 1 and a conductive paste 9 that contains silver or a metal material principally containing silver is then provided in the via-hole 1a.

In the second step shown in FIG. 3, the green sheet 8 and the conductive paste 9 are fired at a temperature of at 800° C. to 900° C. such that the green sheet 8 is converted into the ceramic substrate 1, the conductive paste 9 is converted into the via-conductor 2, silver in the conductive paste 9 is diffused in the ceramic substrate 1, and the silver deposit 2a is formed on the surface portion of the ceramic substrate 1. In this step, the cavities 3 are formed between the via-conductor 2 and the wall of the via-hole 1a.

In the third step shown in FIG. 4, the catalyst layer 4 is formed over the exposed face of the via-conductor 2 and the surface portion of the ceramic substrate 1 by immersing the ceramic substrate 1 in a catalyst solution containing palladium such that the portions of the catalyst layer 4 occupy the cavities 3.

In the fourth step shown in FIG. 5, the metal layer 5 is provided on the catalyst layer 4 by electroless plating. The catalyst layer 4 and the metal layer 5 extend over the exposed face of the via-conductor 2 to the ceramic substrate 1 and have gentle slopes.

In the fifth step shown in FIG. 6, the metal thin-film pattern 6 is formed over the metal layer 5 and the ceramic substrate 1 such that the metal thin-film pattern 6 is connected to the metal layer 5 with the catalyst layer 4 disposed therebetween, whereby the wiring board is obtained.

What is claimed is:

1. A wiring board in which silver is deposited near a via-conductor, comprising:
a ceramic substrate having a via-hole;
a via-conductor disposed in the via-hole; and
a metal thin-film pattern which is disposed on the ceramic substrate such that the metal thin-film pattern is connected to the via-conductor,
wherein the via-conductor contains silver or a material principally containing silver, a silver deposit that is a piece of the via-conductor is disposed on a surface portion of the ceramic substrate that is located near the via-hole, a catalyst layer containing a metal material is disposed over an exposed face of the via-conductor and the surface portion of the ceramic substrate, a metal layer is disposed on the catalyst layer, and the metal thin-film pattern is disposed over the metal layer and the ceramic substrate.

2. The wiring board according to claim 1, wherein the catalyst layer contains palladium.

3. The wiring board according to claim 2, wherein the metal layer contains nickel phosphide.

4. The wiring board according to claim 3, wherein the ceramic substrate is made of low-temperature co-fired ceramic and the metal thin-film pattern contains copper or a material principally containing copper.

5. A method for manufacturing a wiring board in which silver is deposited near a via-conductor, comprising:
a step of forming a via-hole in a ceramic green sheet;
a step of providing a conductive paste containing silver or a metal material principally containing silver in the via-hole;
a step of firing the green sheet and the conductive paste such that the green sheet is converted into the ceramic substrate, the conductive paste is converted into the via-conductor, silver in the conductive paste is diffused in the ceramic substrate, and a silver deposit is formed on a surface portion of the ceramic substrate that is located near the via-hole;
a step of providing a catalyst layer containing a metal material over an exposed face of the via-conductor and the surface portion of the ceramic substrate; and
a step of providing a metal layer on the catalyst layer.

6. The method according to claim 5, wherein the metal layer is overlaid with a metal thin-film pattern containing copper or a material principally containing copper.

7. The method according to claim 6, wherein the catalyst layer contains palladium.

8. The method according to claim 7, wherein the metal layer contains nickel phosphide.

9. The method according to claim 8, wherein the green sheet contains a material for forming a low-temperature co-fired ceramic substrate and the green sheet and the conductive paste are fired at a temperature of about 800° C. to 900° C.
